(19) United States
(12) Patent Application Publication
(10) Pub. No.: US 2010/0066707 A1
(43) Pub. Date: Mar. 18, 2010

(54) A Digital to Analogue Converter

(76) Inventor: Patrick Zebedee, Oxfordshire (GB)

Correspondence Address: HARNESS, DICKEY & PIERCE, P.L.C., P.O. BOX 8910, RESTON, VA, 20195, US

(21) Appl. No.: 12/308,554

(22) PCT Filed: Aug. 1, 2007
(86) PCT No.: PCT/JP2007/065473

§ 371 Date: Dec. 18, 2008

(30) Foreign Application Priority Data
Aug. 11, 2006 (GB) 0615940.4

(51) Int. Cl. G09G 5/00; H03M 1/66; G09G 3/36

(52) U.S. Cl. 345/204; 341/150; 345/98

(57) ABSTRACT

In one embodiment of the present invention, a digital/analogue converter for converting an input n-bit digital code includes: a switched capacitor digital/analogue converter including a plurality of capacitors. The lower plate of each is connectable, dependent on the input digital code, to either a first reference voltage or a second reference voltage different from the first reference voltage. The converter also includes at least one further capacitor, and a switching arrangement for connecting the lower plate of the or each first further capacitor to either a third reference voltage or a fourth reference voltage different from the third reference voltage. The input to the first switching arrangement is independent of the input digital code. In the decoding phase, the output voltage floats to a voltage that depends on both the input data code and the direction and magnitude of charge injection across the further capacitor(s).

### TECHNICAL FIELD

The present invention relates to a digital/analogue converter, in particular to a digital/analogue converter capable of directly driving a load capacitance without the need to provide a buffer amplifier between the converter and the load. Such a converter is known as a “bufferless” converter.

### BACKGROUND ART

In a liquid crystal display (LCD), a layer of liquid crystal material is sandwiched between two electrodes (both of which, in the case of a transmissive liquid crystal display, are transparent). In operation first and second voltages are applied respectively to the electrodes, and the state of the liquid crystal material is dictated by the absolute value of the difference between the first voltage and the second voltage. The state of the liquid crystal material controls how much light is passed through the liquid crystal display, and thus the brightness.

A liquid crystal display generally comprises a polarity of independently addressable picture elements or “pixels”. In an active matrix LCD, one electrode is usually common to all pixels (the “common electrode” or “counter electrode”), while the other electrode is patterned to define a polarity of independently addressable electrodes, each of which corresponds to a pixel (the “pixel electrodes”). A simplified diagram of a pixel is shown in FIG. 1. VCOM represents the voltage applied to the counter electrode 1 of the pixel, while the source line SL, gate line GL and pixel transistor 3 control the voltage applied to the pixel electrode 2 of the pixel. In brief, suitable drive voltages are applied to the source line SL by a display driver DD and to the gate line GL by a suitable drive circuit (not shown in FIG. 1). A suitable voltage to switch the pixel transistor ON is applied to the gate line GL, which is connected to the gate of the pixel transistor. While the pixel transistor 3 is switched ON the pixel electrode is connected to the source line SL and the pixel may be addressed by applying a suitable voltage to the source line.

To prevent long-term degradation of the liquid crystal material in a display, the liquid crystal material must be driven to alternating positive and negative voltages each time it is refreshed (which occurs generally 50-60 times per second), such that the time-averaged dc voltage across the liquid crystal material is zero.

Consider a normally white LCD, where
The “white voltage” (the voltage that must be applied across the liquid crystal material to give 100% transmission of light), V_{W}=1V
The “black voltage” (the voltage that must be applied across the liquid crystal material to give 0% transmission of light), V_{B}=3V

In this example, it is possible to achieve an alternating voltage across the liquid crystal material in one of two ways:
The counter electrode voltage VCOM can be fixed, and the voltage V_{PIXEL} applied to the pixel electrode can be driven alternately to values above and below the fixed value (see FIG. 2(a)). For example, if the counter electrode voltage VCOM is fixed at 2V, the pixel voltage may be alternately in the range 3 to 5V and the range 1 to −1V.
The range for the pixel voltage can be chosen to cover the range of required LC voltages (V_{B}−V_{W}=2V), and counter electrode voltage VCOM can alternate to give the correct dc level to the liquid crystal (see FIG. 2(b)). For example, the pixel voltage V_{PIXEL} may always be in the range 0 to 2V, and the counter electrode voltage VCOM may alternate between −1V and 3V.

It can be seen that use of an alternating counter electrode voltage VCOM reduces the range of voltages required to be supplied to the pixel electrode 2, and therefore simplifies the design of the digital/analogue converters (DACs) which generate these voltages. In typical systems, the counter electrode voltage VCOM alternates every row time (approximately every 50 μs).

However, use of an alternating counter electrode voltage VCOM also has disadvantages:
The counter electrode 1 presents a large capacitance, which therefore takes time to charge. During this time, data cannot be written to the pixels, so the time between rows (blanking time) is increased.
The counter electrode 1 is a large area of conductor, which is therefore susceptible to electro-static discharge (ESD). The usual solution to ESD is to provide a low-resistance path to ground via a protection diode at the point where connection is made to the glass of the display, but such circuits usually contain resistors and so are generally omitted for the counter electrode (so that it charges as quickly as possible). As a result, the counter electrode provides a conduction path into the VCOM driver circuit, which may be damaged by ESD.
Since the load on counter electrode voltage VCOM is large, it is often driven by a very large op-amp buffer, which consumes a large quiescent current. However, since the counter electrode voltage VCOM is switched infrequently, only a small proportion of this current is used to drive the load, with the remainder flowing to ground through the buffer, consuming unnecessary power.

A further consideration is that it is important that the absolute value of the voltage applied to the LC in a positive cycle is the same as the absolute value of the voltage applied to the LC in a negative cycle. If this is not the case, the pixel brightness will vary from one cycle to the next, and the image will appear to flicker.

In practice, it is difficult to accurately predict the value of the pixel voltage before the display is assembled. Most importantly, switches (including the pixel switch) inject charge onto the pixel voltage, causing the voltage to be either increased or decreased relative to the DAC output. This effect applies equally to both the positive and negative cycles, so that the system has a dc offset.

For example, if charge injection reduces the pixel voltage, the voltage across the LC will be decreased when VCOM is low, and increased when VCOM is high, leading to a lighter and darker pixel respectively. The pixels will therefore appear to flicker, being lighter on odd frames and darker on even ones.

To correct for this effect, the offset must be corrected. There are two ways to do this (either method can be applied to the fixed or alternating VCOM systems, or they can be combined):
An offset can be applied to the counter electrode voltage VCOM, as denoted by the shaded voltage ranges in FIG. 3(a); and/or
An offset can be applied to the pixel voltage, e.g. in the voltage applied by the DAC to a source line, as denoted by the shaded voltage ranges in FIG. 3(b).

In general, it is preferable to minimise the number of voltage references required in a system. Each reference must be accurately generated, and then buffered (if it will supply current).

To reduce system complexity, it would be preferable for:
the DACs that supply the pixel voltage to use as the reference voltages the same voltages as provided by the supply rails for, for example, logic circuits and clock circuits in the DAC (or other circuits in the system);
the counter electrode voltage VCOM to be fixed, ideally to ground (to overcome the problem ESD);
or (if VCOM cannot be fixed) the difference between the high and low values of counter electrode voltage VCOM to be the same as the voltage of one supply rail. For example, in a system with supply rails of 0V, 3V and 5V, the difference between the high and low values of VCOM would ideally be 3V or 5V. In this case, the counter electrode voltage VCOM could be driven by a digital inverter, which consumes less quiescent current than an op-amp buffer.

Note that it is possible to generate an adjustable dc offset for VCOM more easily, since this reference is not required to supply current.

FIG. 4 of the accompanying drawings illustrates a known type of switched capacitor digital/analogue converter (DAC) for converting an n-bit digital word (or n-bit digital “code”) to a corresponding analogue output. The DAC comprises n-capacitors C₁, . . . , Cₙ. The DAC further comprises a terminating capacitor C_{TERM} connected between the input of a unity gain buffer 4 and ground. The first electrodes of the capacitors C₁, . . . , Cₙ are connected together and to the first terminal of the terminating capacitor C_{TERM}. The second terminal of each of the capacitors C₁, . . . , Cₙ is connected to a respective switch, such as 5, which selectively connects the second electrode to a first or second reference voltage input V₁ or V₂ in accordance with the state or value of a corresponding bit of the digital word. The output of the buffer 4 drives a capacitive load C_{LOAD}, for example in the form of a data line or column electrode of an active matrix of a liquid crystal device.

The DAC has two phases of operation, namely a resetting or “zeroing” phase and a converting or “decoding” phase, controlled by timing signals which are not illustrated in FIG. 4. During the zeroing phase, the first and second electrodes of the capacitors C₁, . . . , Cₙ and the first electrode of the terminating capacitor C_{TERM} are connected together by an electronic switch 6 and to the first reference voltage input V₁. The capacitors C₁, . . . , Cₙ are therefore discharged so that the total charge stored in the DAC is equal to V₁C_{TERM}.

During the decoding phase, the second electrode of each capacitor Cᵢ is connected to the first reference voltage input V₁ or to the second reference voltage input V₂ according to the value of the ith bit of the digital input word. The charge stored in the DAC is given by:

$$Q = {\sum }_{i} {b}_{i} {C}_{i} ( {V}_{DAC} - {V}_{2} ) + {\sum }_{i} ( 1 - {b}_{i} ) {C}_{i} ( {V}_{DAC} - {V}_{1} ) + {V}_{DAC} {C}_{TERM} \qquad ( 1 )$$

where bᵢ is the ith bit of the input digital word and V_{DAC} is the voltage at the first electrodes of the capacitors C₁, . . . , Cₙ and C_{TERM}. The output voltage is therefore given by:

$${V}_{DAC} = {V}_{OUT} = \frac{{\sum }_{i} {b}_{i} {C}_{i}}{{\sum }_{i} {C}_{i} + {C}_{TERM}} ( {V}_{2} - {V}_{1} ) + {V}_{1} \qquad ( 2 )$$

In general, Cᵢ=2⁽ⁱ⁻¹⁾C₁ and C₁=C_{TERM}. This results in a set of output voltages which are linearly related to the input digital word.

In order to isolate the load capacitance from the DAC and to prevent it from affecting the conversion process, the unity gain buffer 4 is provided. However, such buffers are a substantial source of power consumption, and it is therefore desirable to omit the buffer 4 in a low power system. In this case, the load capacitance replaces C_{TERM}, as shown in FIG. 5.

UK patent application No. 0500537.6 discloses a DAC suitable for use without a buffer amplifier. This DAC is shown in FIG. 6.

The components of an n-bit DAC of UK patent application No. 0500537.6 are an (n−1)-bit switched capacitor DAC of the type described in FIG. 4 and three reference voltage sources, V₁, V₂, V₃. One of the reference voltage sources (V₁) is connected to the top plate of the capacitor array during the zeroing phase as switch 7 is closed by a timing signal F₁. The other reference voltage sources (V₂, V₃) are connected to the bottom plates of the capacitors Cᵢ according to the input data and timing signals F₁, F₂, by means of respective switches 8.

In the preferred embodiment, the voltages on the bottom plates are configured so that the capacitors can inject charge onto the DAC output in either a positive or negative sense. In this way, the output of the DAC covers a range of voltages symmetrically above and below the first reference voltage, as shown in FIG. 6: The output voltage is given by

$$\begin{matrix}{V}_{DAC} = {V}_{1} + \frac{{\sum }_{i = 1}^{n - 1} {b}_{i} {C}_{i}}{{\sum }_{i = 1}^{n - 1} {C}_{i} + {C}_{TERM}} ( {V}_{3} - {V}_{2} ) \\ = {V}_{1} - \frac{{\sum }_{i = 1}^{n - 1} ( 1 - {b}_{i} ) {C}_{i}}{{\sum }_{i = 1}^{n - 1} {C}_{i} + {C}_{TERM}} ( {V}_{3} - {V}_{2} )\end{matrix} \qquad ( 3 )$$

when the most significant bit, bₙ, is 1 or 0 respectively. FIG. 7 illustrates this output.

The dc level of the output voltage is set by V₁, while the output range of the DAC is set by the relative size of the switched capacitors and the terminating capacitor (or load, if the DAC is used without a buffer), and the difference between V₃ and V₂. It is therefore possible to choose V₂ and V₃ arbitrarily, provided the corresponding capacitor sizes are suitable. Thus these references may be selected to be equal to voltages already available within the system, such as ground or a power supply.

However, the first reference voltage V₁ dictates the dc level of the output voltage, and is less flexible. For example, an LCD requiring voltages in the range 1-3V, would need V₁=2V, and thus may require an additional 2V reference to be generated. Generation of this voltage increases the system complexity and the power consumed.

Alternatively, the DAC may be configured so that the output voltage is always greater (or less) than V₁. In this case, the output is given by

$${V}_{DAC} = {V}_{1} + \frac{{\sum }_{i = 1}^{n - 1} {b}_{i} {C}_{i}}{{\sum }_{i = 1}^{n - 1} {C}_{i} + {C}_{TERM}} ( {V}_{3} - {V}_{2} ) \qquad ( 4 )$$

As before, V₂ and V₃ can be chosen relatively freely, while V₁ is constrained by the required dc level of the output.

In the case of where a pixel of a liquid crystal display is driven with a fixed counter electrode voltage VCOM a wide range of pixel voltages are required, which must be generated by the DAC used to drive the source line SL of FIG. 1. This necessitates either large capacitors (especially if the DAC is used without a buffer, since the DAC capacitors must be large relative to the load—which is itself large), or a high value of (V₃−V₂). Neither of these is desirable: large capacitors increase the area required for the DAC, while a high value of (V₃−V₂) may make the voltages more difficult to generate.

It would therefore be advantageous to reduce the output range required for the DAC, so allowing relatively small capacitors and relatively low voltages to be used.

UK patent application No. 0506868.8 describes a switched capacitor DAC with additional capacitors, as shown in FIG. 8. The switched capacitor DAC of FIG. 8 consists of two switched capacitor DACs 9,9′ each of which has the general form shown in FIG. 6. The output of one or other of the DACs is selected by switches 11,11′ controlled by the most significant bit of the input data code.

Each of the switched capacitor DACs 9,9′ comprises a plurality of terminating capacitors Cₜₑᵣₘ₀, Cₜₑᵣₘ₁, Cₜₑᵣₘ₂, C_{term0′}, C_{term1′}, C_{term2′}. The upper plate of each additional capacitor is connected via a respective switch 10,10′ to the output of the respective DAC output, and the lower plate of each additional capacitor is connected to the second or third reference voltage (to the third reference voltage V₃ in FIG. 8). The additional capacitors are thus either connected to the DAC output or left floating—they do not inject charge into the DAC. The switches 10,10′ that determine whether an additional capacitor is connected to the DAC output or left floating are controlled by respective bits of the input data code—that is, the additional capacitors are controlled by the same input data as the ordinary switched capacitors in the DAC.

U.S. Pat. No. 6,906,653 describes a switched capacitor DAC having capacitors C1-C4. The switched capacitor DAC is also provided with an additional capacitor C0, as shown in FIG. 9. The capacitors are scaled such that C0:C1:C2:C3:C4=1:1:2:4:8. The bottom plate of the additional capacitor C0 is switched between one reference voltage and the buffered DAC output voltage, by a switch SW_{R0} under the control of a clock signal CK. The bottom plates of the remaining capacitors are switchable by switches SW_{R1}-SW_{R4}, SW_{D1}-SW_{D4} between one of two reference voltages V_{T}, V_{B}, in the manner described with reference to FIG. 4 above.

U.S. Pat. No. 4,937,578 describes a switched capacitor DAC for decoding two's complement data, as shown in see FIG. 10. Two's complement data invert a binary number by inverting every bit and adding one to the result, and the switched capacitor DAC of U.S. Pat. No. 4,937,578 includes an additional capacitor 12 to create an offset when the required output data is negative. The additional capacitor creates an offset to mimic this addition of one. The additional capacitor is switched by means of a switch SWA between two reference voltages V_{R}, V_{G} in response to a timing signal, but controlled by the input data code. The remaining capacitors CO . . . 16CO and their associated switches SW1 . . . SW5 form a switched capacitor DAC of the general type shown in FIG. 4. Depending on the input data, the additional capacitor does not always switch.

US patent application No. 2003/0206038 discloses an analogue-to-digital converter which comprises two digital-to-analogue converters. Each DAC comprises a plurality of switched capacitors, each having a first terminal connected to the output of the DAC. The second terminal of each of the capacitors is, after a sampling phase, connected to either a positive reference voltage or a negative reference voltage. The output voltages of the two DACs converge during a second phase of operation. Each DAC further comprises a further capacitor, which has its first terminal connected to the output of the DAC; its second terminal may be switched so as to be connected to one of two preset voltages. The switching of the further capacitors is controlled in the second phase so as to keep the voltage difference between the output voltages of the two DACs below a threshold at which it will not turn on any parasitic diodes, and any boost voltage provided by the further capacitors is removed as soon as the voltage difference between the output voltages of the two DACs output voltages has reduced to a level at which it cannot turn on any parasitic diodes.

### DISCLOSURE OF INVENTION

A first aspect of the present invention provides a digital/analogue converter for converting an input n-bit digital code, where n is an integer greater than 1, comprising a switched capacitor digital/analogue converter having a plurality of capacitors, a first terminal of each capacitor being connected to an output of the converter, and a second terminal of each capacitor being connectable, dependent on a respective bit of the input data code, to either a first reference voltage or a second reference voltage different from the first reference voltage; and further comprising a first further capacitor, a first terminal of the first further capacitor being connected to the output of the converter; and a first switching arrangement for connecting a second terminal of the first further capacitor to either a third reference voltage or a fourth reference voltage different from the third reference voltage, wherein an input to the first switching arrangement is independent of the input digital code.

The one or more further capacitors effectively adjust the voltage to which the DAC zeros during the zeroing phase. This allows the output voltage range of the DAC to be adjusted without requiring an additional reference voltage input. The first switching arrangement, and therefore the amount of charge injected by the one or more further capacitors, are controlled by one or more signals that are input to the first switching arrangement and that are all independent of the input digital code. The switching arrangement, and the input signal(s) thereto, may also be arranged so as to control the direction into which charge is injected into the one or more further capacitors.

The boost voltage applied is determined by the signal(s) input to the first switching arrangement, and so is independent of the input digital code—so that, for a given input to the first switching arrangement, the same boost voltage is provided for all input digital codes. Where the direction into which charge is injected into the one or more further capacitors can be controlled, the direction into which charge is injected into the one or more further capacitors is, for a given input to the first switching arrangement, again the same for all input digital codes

The connection of the second terminal of the first further capacitor is preferably maintained throughout a decoding phase—that is, the state of the first switching arrangement preferably does not change in the decoding phase. In contrast, in the analogue-to-digital converter of US patent application No. 2003/0206038 the boost voltage is removed during the second phase of operation, as explained above. The point in the second phase at which this boost is removed will depend on the input to the analogue-to-digital converter.

The converter may comprise two or more first further capacitors, and the choice of reference voltage to be connected to the second terminal of one of the first further capacitors may be independent of the choice of reference voltage to be connected to the second terminal of the or each other first further capacitor. Each first further capacitor may have their second terminal connectable to either the third reference voltage or the fourth reference voltage, although in principle, it would be possible for the voltages that may be connected to the second terminal of one first further capacitor to be different from the third and fourth reference voltages.

The switched capacitor digital/analogue converter may comprise n capacitors. For example, a switched capacitor DAC of the type shown in FIG. 4 may be used.

The switched capacitor digital/analogue converter may be a bi-directional switched capacitor digital/analogue converter. By a “bi-directional switched capacitor digital/analogue converter” is meant a switched capacitor DAC having a voltage output of the form given by equation (3) and shown in FIG. 7, in which the output covers a range of voltages above and below the reference voltage V₁. As an example, a bi-directional switched capacitor digital/analogue converter may have the general form shown in FIG. 6 of the present application (in this case, the switched capacitor digital/analogue converter will comprise (n−1) capacitors).

The input to the first switching arrangement may comprise a clock signal. This allows charge injection across the capacitors of the switched capacitor DAC to be synchronised with the decoding phase of the DAC. Charge injected during the zeroing phase would be lost and would have no effect on the output voltage.

Additionally or alternatively, the input to the first switching arrangement may comprise tuning data. Where the DAC is being used to drive a liquid crystal display device, as an example, the tuning data may be used to ensure that the absolute value of the voltage applied to the liquid crystal material is the same in both positive and negative cycles, to eliminate flicker.

Additionally or alternatively, the input to the first switching arrangement may comprise a state signal. Where the DAC is being used to drive a system, a “state signal” is internal to the operation of the system, is not perceptible to a user, and is indicative of the state of the system in some way. For example, where the DAC is being used to drive a liquid crystal display device, the state signal may correspond to an internal state of the display device, for example such as whether the liquid crystal should be driven with a positive voltage or a negative voltage in the current row time. In general, the state signal may be any signal that varies in time and that represents a state of the system that is being driven by the converter.

The converter may further comprise at least one second further capacitor, a first terminal of the or each second further capacitor being connected to the output of the converter, and a second switching arrangement for connecting a second terminal of the or each second further capacitor to either a fifth reference voltage or a sixth reference voltage different from the fifth reference voltage, wherein an input to the second switching arrangement is independent of the input n-bit digital code and is independent of the input to the first switching arrangement.

The input to the first switching arrangement may comprise a clock signal and tuning data, and the input to the second switching arrangement may comprise a clock signal and a signal indicative of the state of a system.

The converter may further comprise a third switching arrangement for connecting, during a zeroing phase, the first terminals of the capacitors of the switched capacitor digital/analogue converter to a reference voltage. The third switching arrangement may be adapted to, in a decoding phase, isolate the first terminal of each capacitor of the switched capacitor digital/analogue converter from the reference voltage.

The third switching arrangement may connect, during the zeroing phase, the first terminals of the capacitors of the switched capacitor digital/analogue converter to one of the first and second reference voltages. This embodiment may be applied to a DAC having the general form shown in FIG. 4 of the present application, or it may be applied to a bi-directional DAC having the general form shown in FIG. 6 in which one of V₂ and V₃ is equal to V₁.

Alternatively, the third switching arrangement may connect, during the zeroing phase, the first terminals of the capacitors of the switched capacitor digital/analogue converter to a reference voltage different from both the first reference voltage and the second reference voltage. This embodiment may be applied to, for example, a DAC of the general form shown in FIG. 6 in which the reference voltages V₁, V₂, and V₃ are all different from one another.

Alternatively, the third switching arrangement may connect, during a zeroing phase, the first terminals of the capacitors of the switched capacitor digital/analogue converter to either a seventh reference voltage or to an eighth reference voltage different from the seventh reference voltage, and an input to the third switching arrangement may be independent of the input digital code. In this embodiment, for a given input digital code the converter may output two or more different output voltages depending on which of the reference voltages is selected by the third switching arrangement.

The converter may be a buffer-less converter and the output may be for direct connection to a capacitive load.

The third reference voltage may be equal to the first reference voltage, and the fourth reference voltage may be equal to the second reference voltage.

The fifth reference voltage may be equal to the first reference voltage, and the sixth reference voltage may be equal to the second reference voltage.

A second aspect of the present invention provides a display driver comprising a converter of the first aspect.

A third aspect of the present invention provides a display comprising an image display layer and a driver of the second aspect providing at least a select region of the image display layer. For example, the display driver may be used to drive one or more source lines SL of a pixelated active matrix display having the general arrangement shown in FIG. 1.

The input to the first switching arrangement may be dependent on a state of the image display layer. The image display layer may be a layer of liquid crystal material.

The input to the switching arrangement may be dependent on the polarity of the liquid crystal material.

The invention also provides a digital/analogue converter for converting an input n-bit digital code, where n is an integer greater than one, comprising: a switched capacitor digital/analogue converter having an output and an n-bit digital input; and a switching arrangement; wherein the switching arrangement is adapted, in a zeroing phase of operation, to connect one of a plurality of reference voltages to the first plate of at least one capacitor of the switched capacitor digital/analogue converter; and wherein an input to the switching arrangement is independent of the input n-bit digital code.

### BRIEF DESCRIPTION OF DRAWINGS

Preferred embodiments of the present invention will now be described by way of illustrative example, with reference to accompanying figures in which:

FIG. 1 is a schematic illustration of a pixel of a liquid crystal display;

FIG. 2(a) shows pixel voltages and counter electrode voltages for a drive scheme in which a pixel is driven with a DC counter electrode voltage;

FIG. 2(b) shows pixel voltages and counter electrode voltages for a drive scheme in which a pixel is driven with an alternating counter electrode voltage;

FIG. 3(a) shows pixel voltages and counter electrode voltages for a drive scheme corresponding to FIG. 2(b), and in which the counter electrode voltages is varied to avoid flicker;

FIG. 3(b) shows pixel voltages and counter electrode voltages for a drive scheme corresponding to FIG. 2(b), and in which pixel voltages are varied to avoid flicker;

FIG. 4 shows a typical switched capacitor DAC;

FIG. 5 shows a buffer-less switched capacitor DAC in which the output is connected directly to a load;

FIG. 6 shows a three reference bi-directional DAC;

FIG. 7 shows the output voltage range for the bi-directional DAC of FIG. 6;

FIG. 8 is a block circuit diagram of a switched capacitor DAC provided with a plurality of terminating capacitors;

FIG. 9 is a block circuit diagram of a DAC having an additional capacitor switchable between one reference voltage and the buffered DAC digital output under the control of a clock signal;

FIG. 10 is a block circuit diagram of a switched capacitor DAC for decoding two's complement data;

FIG. 11 is a block circuit diagram of a DAC according to a first embodiment of the present invention;

FIG. 12(a) is a block circuit diagram of a DAC according to a second embodiment of the present invention;

FIG. 12(b) illustrates output voltages for the converter of FIG. 12(a);

FIG. 13(a) is a block circuit diagram of a converter according to a third embodiment of the present invention;

FIGS. 13(b) and 13(c) show output voltages for the converter of FIG. 13(a);

FIG. 14(a) is a block circuit diagram of a converter according to a further embodiment of the present invention;

FIG. 14(b) shows output voltages for the converter of FIG. 14(a);

FIG. 15(a) is a block circuit diagram of a converter according to a fifth embodiment of the present invention;

FIG. 15(b) shows output voltages for the converter of FIG. 15(a);

FIG. 16(a) is a block circuit diagram of a converter according to a sixth embodiment of the present invention;

FIG. 16(b) shows output voltages for the converter of FIG. 16(a);

FIG. 17(a) is a block circuit diagram of a converter according to a seventh embodiment of the present invention;

FIG. 17(b) shows output voltages for the converter of FIG. 17(a);

FIG. 18(a) is a block circuit diagram of a converter according to an eighth embodiment of the present invention;

FIG. 18(b) shows output voltages for the converter of FIG. 18(a); and

FIG. 19 is a block circuit diagram of a converter according to a ninth embodiment of the present invention.

### BEST MODE FOR CARRYING OUT THE INVENTION

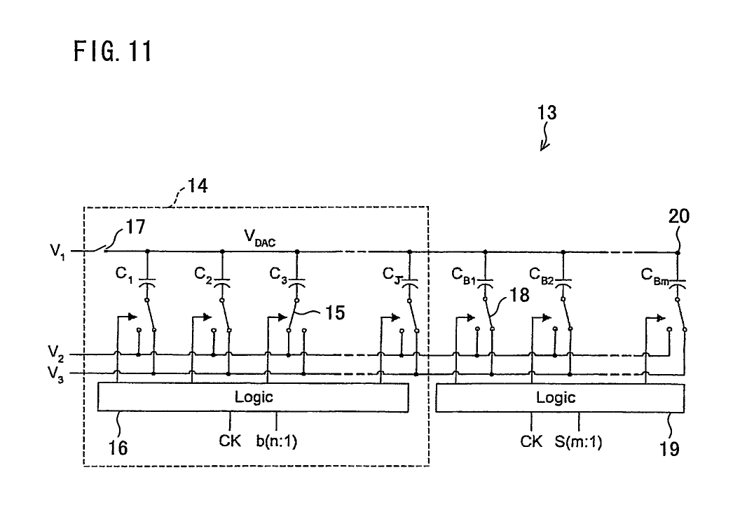

FIG. 11 shows an n-bit digital/analogue converter according to a first embodiment of the present invention. The DAC 13 of FIG. 11 is for converting an input n-bit digital code (where n is greater than 1) into an output voltage. The converter 13 of FIG. 11 comprises a switched capacitor digital/analogue converter 14 containing J capacitors C₁ . . . C_{J} whose upper plate is connected to an output of the converter and whose lower plate may be connected to one of two reference voltages V₂, V₃ (where V₂ ¹ V₃). The connection of the lower plate of each capacitors C₁ . . . C_{J} is determined by a respective switch 15, which is controlled by a respective output from a logic circuit 16.

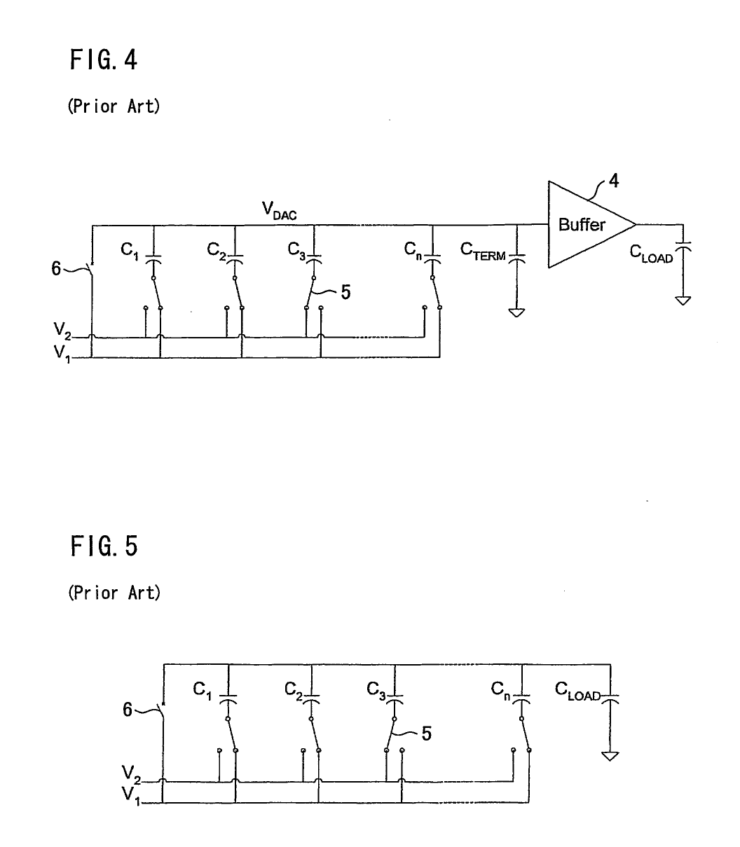

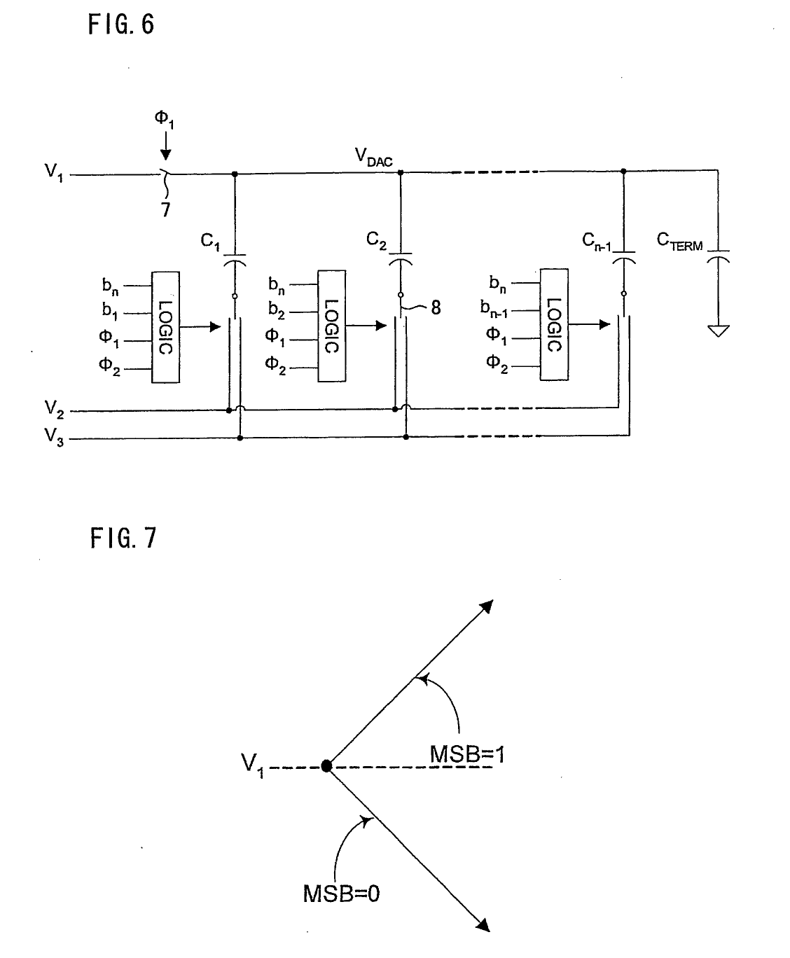

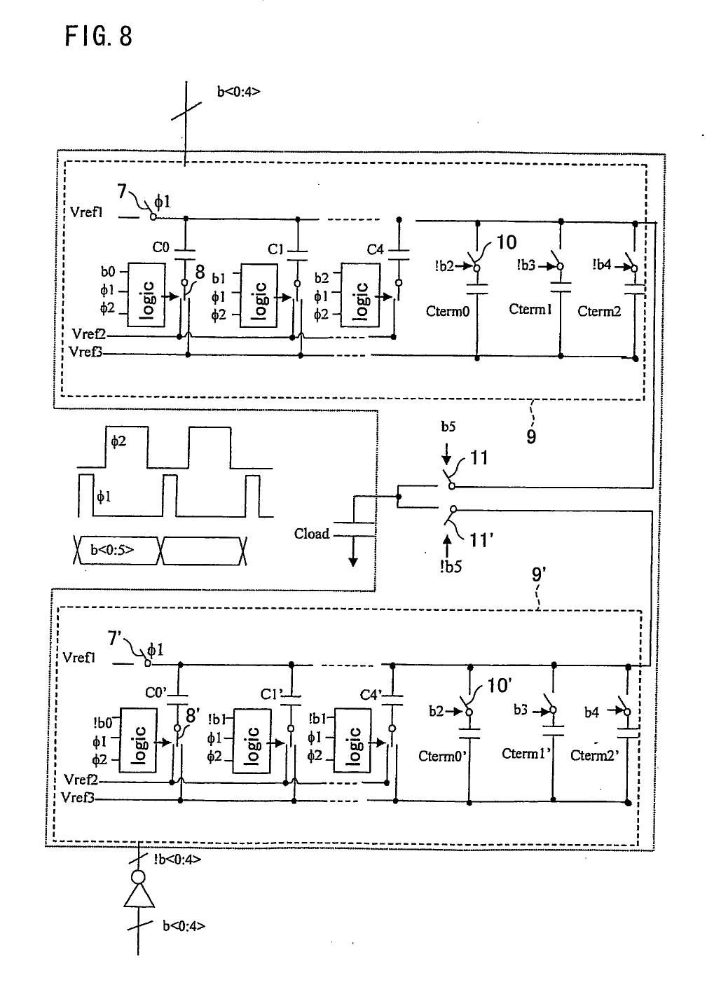

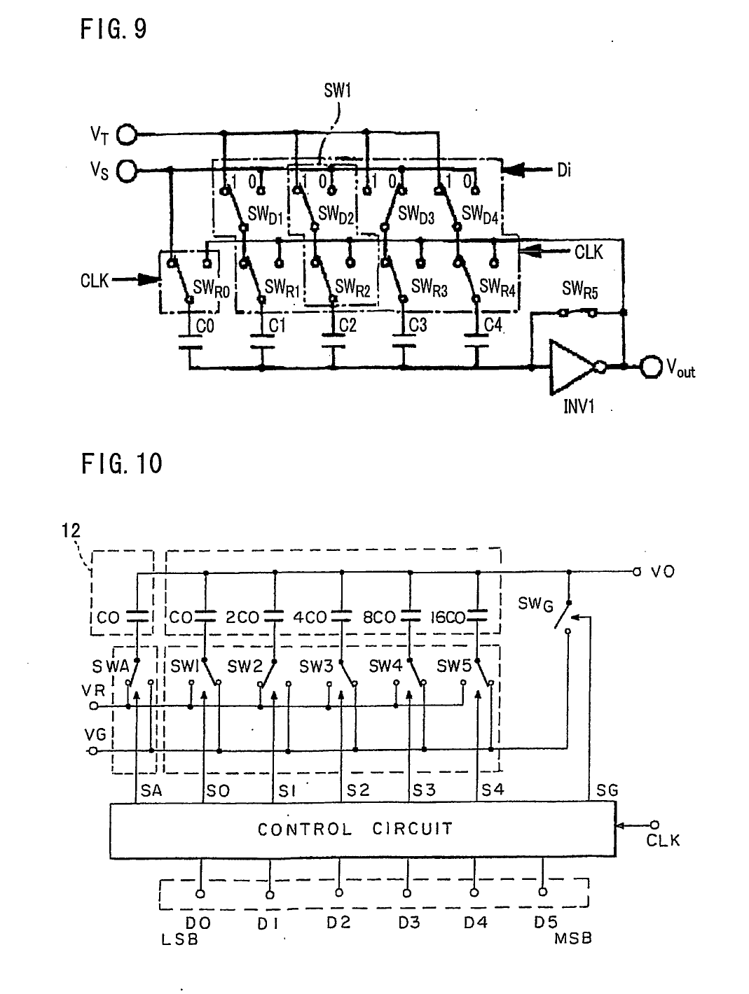

The present invention will be described with particular reference to a bi-directional DAC of the general type shown in FIG. 6. In this case, the DAC 13 will include (n−1) capacitors: —that is, J=n−1. The invention is not, however, limited to use with a bi-directional DAC of the general type shown in FIG. 6, and the invention may be applied to any switched capacitor DAC. For example, the DAC 13 of FIG. 11 may alternatively be a switched capacitor DAC of the general type shown in FIG. 4, in which case the DAC will include n capacitors: —that is, J=n.

The inputs to the logic circuit 16 are a timing signal CK, and the input n-bit digital code (denoted in FIG. 11 as “b(n:1)”). The upper plates of the capacitors C₁ . . . C_{J} are connectable to a further reference voltage V₁, by means of a switch 17. (In the description, the term “upper plate” is used to denote the plate of a capacitor that is connected to the output 20 of the converter, and the other plate of a capacitor will be referred to as the “lower plate”. This wording is used purely for convenience and does not limit the DAC to any specific orientation in use.)

The DAC of FIG. 11 further comprises m further capacitors C_{B1} . . . C_{Bm}. In FIG. 11 three further capacitors are shown, but the invention is not limited to this and any number m (m³ 1) of further capacitors may be provided. The upper plate of the or each further capacitor is connected to the output of the converter, and to the upper plates of the capacitors C₁ . . . C_{J} of the switched capacitor DAC 14. The lower plate of the or each further capacitor may be connected by a suitable switching arrangement to one or other of a pair of reference voltages. In FIG. 11 the reference voltages to which the lower plate of the or each further capacitor C_{B1} . . . C_{Bm} may be connected are the same reference voltages V₂, V₃ to which the lower plates of the DAC capacitors C₁ . . . C_{J} may be connected, but the invention is not limited to this, and the reference voltages to which the lower plate of the or each further capacitor C_{B1} . . . C_{Bm} may be connected could be different from the reference voltages V₂, V₃. The input to the switching arrangement for the second terminals of the or each further capacitor C_{B1} . . . C_{Bm} is independent of the input digital code.

In the embodiment of FIG. 11, the switching arrangement for the further capacitors C_{B1} . . . C_{Bm} comprises respective switches 18, each controlled by a respective output of a further logic circuit 19. The outputs of the logic circuit 19 are independent of the input digital code b(n:1). In the embodiment of FIG. 11, the inputs to the further logic circuit 19 are a timing signal CK and a “state signal” S. The state signal S may be indicative of the state of, for example, a system that is being driven by the DAC 13. The state signal is independent of the input digital code b(n:1). For example, where the DAC 14 is being used to drive a liquid crystal display device, the input digital code b(n:1) indicates a desired grey level for the displayed image (or of a pixel of the image), while the state signal corresponds to an internal state of the liquid crystal display such as, for example the polarity of the liquid crystal material (that is, whether the liquid crystal is to be driven with a positive voltage or a negative voltage in the current row time). The timing signal CK may be, for example, a clock signal that defines the zeroing phases and the decoding phases.

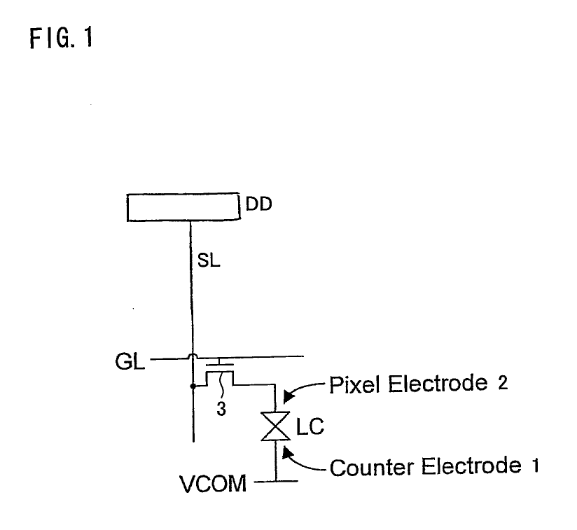

FIG. 11 shows the invention applied to a “buffer-less” DAC, having an output 20 suitable for direct connection to a load capacitance (not shown). By the term “buffer-less DAC” as used herein is meant a DAC in which the unity gain output buffer one of FIG. 1 is not required to be present.

If the DAC 13 of FIG. 11 is incorporated in a display driver for driving, for example, a display device, the load capacitance may, for example, comprise a source line of an active matrix liquid crystal display device.

The DAC 13 of FIG. 11 operates with a zeroing phase followed by a decoding phase. In the zeroing phase, the switch 17 is closed to connect the upper plates of the capacitors C₁ . . . C_{J} of the switched capacitor DAC 14, and the upper plates of the further capacitors C_{B1} . . . C_{Bm} to the reference voltage V₁. The output voltage of the DAC 13 is accordingly charged to the reference voltage V₁.

In the decoding phase the switch 17 is controlled to be opened so as to isolate the upper plates of the capacitors from the reference voltage source V₁.

In a preferred embodiment, as described in co-pending application No. 0500537.6 (the contents of which are hereby incorporated by reference), the connection of the lower plate of each capacitor C₁ . . . C_{J} of the switched capacitor DAC 14 during the zeroing phase and the decoding phase is dependent upon the respective bit bᵢ of the input data code, and on the most significant bit bₙ of the input data code. There are essentially two possibilities for the connection of the lower plate of each capacitor—either (a) the voltage applied to the lower plate of the capacitor during the decoding phase may be different to the voltage that was applied to the lower plate of the capacitor during the zeroing phase, so that charge is injected across the capacitor in the decoding phase or (b) the voltage applied to the lower plate of the capacitor in the decoding phase is the same as the voltage that was applied to the lower plate of the capacitor during the zeroing phase, so that no charge is injected across the ith capacitor Cᵢ during the decoding phase. If charge is injected across the ith capacitor Cᵢ during the decoding phase, the sign of the injected charged is preferably determined by the most significant bit bₙ of the input data code.

The first logic circuit 16 of FIG. 11 may be any suitable logic circuit that controls the switches 15 to control the injection of charge across the i^{th} capacitor Cᵢ in the decoding phase in the manner described above, and described in more detail in UK patent application No. 0500537.6. The logic circuit 16 may control the switches 15 in any of the manners described in the UK patent application No. 0500537.6. If desired, each switch 15 may alternatively be controlled by a separate discrete logic circuit, in the manner shown in FIG. 6 of the present application.

In the decoding phase, the lower plates of the further capacitors C_{B1} . . . C_{Bm} are connected to one of the voltages V₂, V₃. Assume, for example, that the lower plate of each further capacitor C_{B1} . . . C_{Bm} is connected to the reference voltage V₂ in the zeroing phase.

In the decoding phase, the second plate of each further capacitor C_{B1} . . . C_{Bm} may either remain connected to the voltage V₂, or it may be switched so as to be connected to the voltage V₃. The connection of the second plate of each further capacitor C_{B1} . . . C_{Bm} remains unchanged throughout the decoding phase. Where the second terminal of a further capacitor is switched from voltage V₂ to voltage V₃ at the start of the decoding phase, charge is injected across that capacitor in the decoding phase and is shared across all capacitors of the DAC 13. The output voltage V_{DAC} of the DAC 13 thus floats to a voltage that depends on both the input data code and the direction of charge injection across the further capacitors C_{B1} . . . C_{Bm}. That is:

$${V}_{DAC} = {V}_{1} + \frac{{\sum }_{i = 1}^{J} {b}_{i} {C}_{i} + {\sum }_{i = 1}^{m} {S}_{i} {C}_{Bi}}{{\sum }_{i = 1}^{J} {C}_{i} + {\sum }_{i = 1}^{m} {C}_{Bi} + {C}_{TERM}} ( {V}_{3} - {V}_{2} ) \qquad ( 5 )$$

In equation (5), the term Sᵢ denotes the i^{th} bit of the state signal S.

Alternatively, if the second terminals of the boost capacitors were connected to the voltage V₃ in the zeroing phase, and were selectively connected to the voltage V₂ during the decoding phase, the sign of charge injected across the boost capacitors would be reversed and the output voltage of the DAC 13 would be as follows:

$${V}_{DAC} = {V}_{1} + \frac{{\sum }_{i = 1}^{J} {b}_{i} {C}_{i} - {\sum }_{i = 1}^{m} {S}_{i} {C}_{Bi}}{{\sum }_{i = 1}^{J} {C}_{i} + {\sum }_{i = 1}^{m} {C}_{Bi} + {C}_{TERM}} ( {V}_{3} - {V}_{2} ) \qquad ( 6 )$$

Equations (5) and (6) are for injection of charge in only one direction across the capacitors Cᵢ of the switched capacitor DAC 14. If the switched capacitor DAC 14 is a bi-directional switch capacitor DAC, as shown in the embodiment of FIG. 11, the output voltage of the DAC 13 will therefore include voltages above and below the reference voltage V₁, in the manner shown in FIG. 7. In this case equations (5) and (6) would be modified to give two branches of output voltage, one extending above V₁ and one extending below. The lower branch of the output voltage would be given by:

$${V}_{DAC} = {V}_{1} + \frac{- {\sum }_{i = 1}^{J} ( 1 - {b}_{i} ) {C}_{i} + {\sum }_{i = 1}^{m} {S}_{i} {C}_{Bi}}{{\sum }_{i = 1}^{J} {C}_{i} + {\sum }_{i = 1}^{m} {C}_{Bi} + {C}_{TERM}} ( {V}_{3} - {V}_{2} ) . \qquad ( 7 )$$

when the additional capacitors are connected to V₂ during zeroing (as in equation (5)), and by:

$${V}_{DAC} = {V}_{1} - \frac{{\sum }_{i = 1}^{J} ( 1 - {b}_{i} ) {C}_{i} + {\sum }_{i = 1}^{m} {S}_{i} {C}_{Bi}}{{\sum }_{i = 1}^{J} {C}_{i} + {\sum }_{i = 1}^{m} {C}_{Bi} + {C}_{TERM}} ( {V}_{3} - {V}_{2} ) \qquad ( 8 )$$

when the additional capacitors are connected to V₃ during zeroing (as in equation (6)).

In the case of a buffer-less DAC which does not include a terminating capacitor, such as the DAC of FIG. 11, the quantity C_{TERM} in the denominator of equations (5) and (6) is replaced by the load capacitance C_{LOAD}.

The further capacitors C_{B1} . . . C_{Bm} in FIG. 11 effectively adjust, or “boost” the voltage to which the DAC 13 zeros in the zeroing phase. They will accordingly be referred to as “boost capacitors”.

In an embodiment in which two or more boost capacitors are provided, the choice of reference voltage to be connected to the second terminal of one boost capacitors in the decoding phase may be independent of the choice of reference voltage to be connected to the second terminal(s) of the other boost capacitor(s) in the decoding phase.

In FIG. 11, the lower plate of each boost capacitor is connected to either the reference voltage V₂ or the reference voltage V₃. In principle, however, the lower plates of each boost capacitor do not need to be connectable to the same pair of reference voltages. One example where it might be desirable to connect two boost capacitors to difference reference voltages is to provide a small boost (or offset) to the DAC output voltage. If a small boost is required, but the corresponding capacitor size is too small to allow the capacitor to be made accurately, it would be possible to use a larger capacitor and switch it across a lower voltage range. For example, instead of a capacitor of value C/2 with its lower plate switched between V₂ and V₃ a capacitor of value C with its lower plate switched between V₂ and ½(V₂+V₃) might be used, to allow more accurate manufacture of the capacitor. Other, larger boost capacitors may be switched between V₂ and V₃.

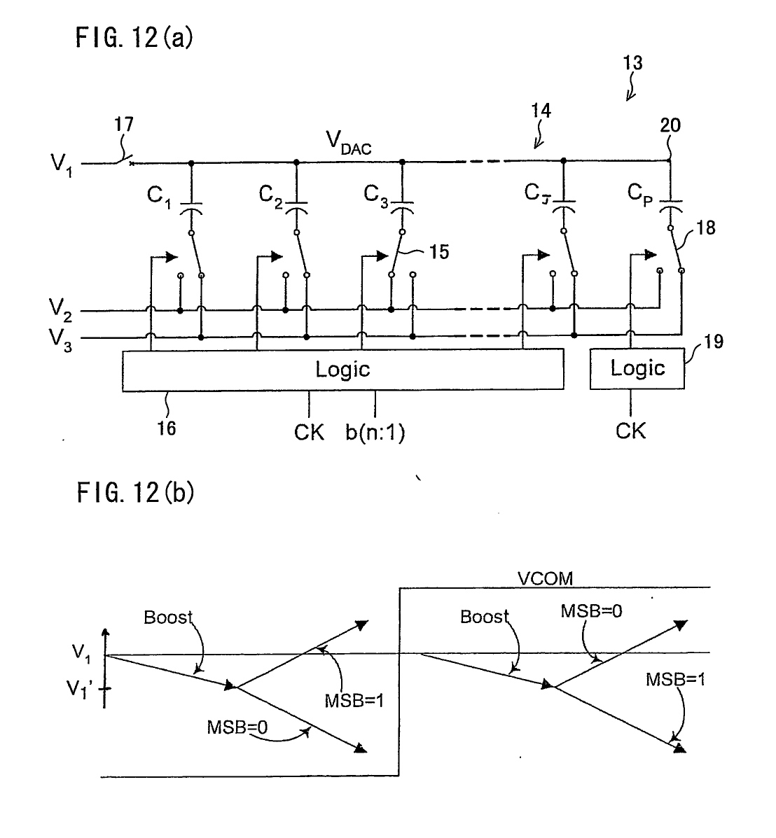

FIG. 12(a) shows a DAC 13 according to a second embodiment of the present invention. This embodiment corresponds generally to the embodiment of FIG. 11, except that it includes only one boost capacitor, Cₚ, and that the logic circuit 19 that controls the connection of the lower plate of the boost capacitor Cₚ has as its only input a clock signal CK. Because the only input to the logic circuit 19 is the clock signal, charge is always injected in the same direction into the boost capacitor Cₚ. (whereas charge may be injected in either direction into the boost capacitors C_{B1}, C_{B2}, C_{B3} of FIG. 11).

FIG. 12(b) is a schematic illustration of the output voltage from the DAC 13 of FIG. 12(a). Instead of the output voltage range including one arm extending above the reference voltage V₁, and one arm extending below the reference voltage V₁, as in FIG. 7, the effect of providing the boost capacitor Cₚ is that the output voltage range includes arms extending above and below a voltage V₁′, which is different from the voltage V₁. In FIG. 12(b) V₁′ is shown as lower that V₁, but V₁′ could alternatively be greater than V₁ if the direction of charge injection across the boost capacitor C_{P} in the decoding phase were reversed.

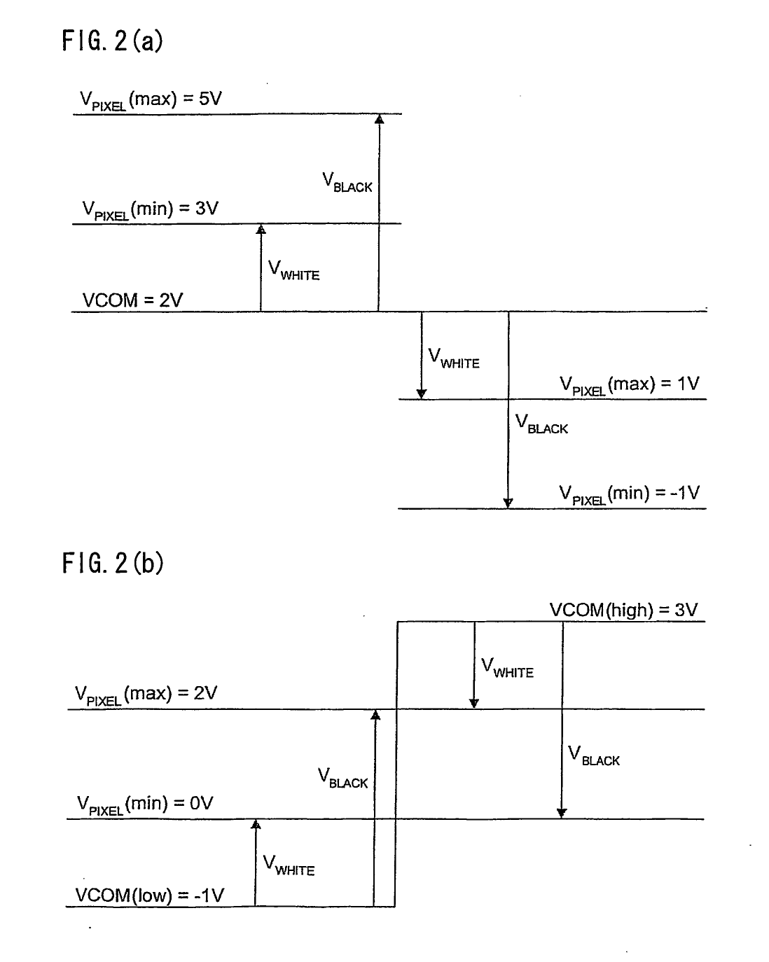

An alternating counter electrode voltage VCOM is superposed in FIG. 12(b). It can be seen that the effect of providing the boost capacitor C_{P} is that the output voltages from the DAC 13 are now suitable for use as the pixel voltages V_{PIXEL} in a drive scheme such as shown in FIG. 2(b). If the boost capacitor Cₚ were not provided, however, the output voltage range of the DAC would not extend down to the lowest required value, V_{PIXEL} (min), shown in FIG. 2(b).

The effect of the boost capacitor C_{P} is shown in FIG. 12(b) by the arrow labelled “boost” that extends from voltage level V₁ to V₁′. (The horizontal extent of this arrow has no significance, and is purely to make the diagrams easier to read.)

The DAC of FIG. 12(a) may be used, for example, to drive a display device according to a drive scheme in which the counter electrode voltage VCOM has an alternating form as shown in FIG. 2(b). If there should exist in the system a voltage that is approximately, but not exactly, the right voltage for use as the reference voltage V₁, the provision of the boost capacitor C_{P} enables the voltage about which the output voltage range is based (or about which the output voltage range is centred in the case of a bi-directional DAC) to be decreased (or increased) from V₁ to a more suitable voltage thereby allowing the output voltages of the DAC to cover the entire desired range of pixel voltages V_{PIXEL}.

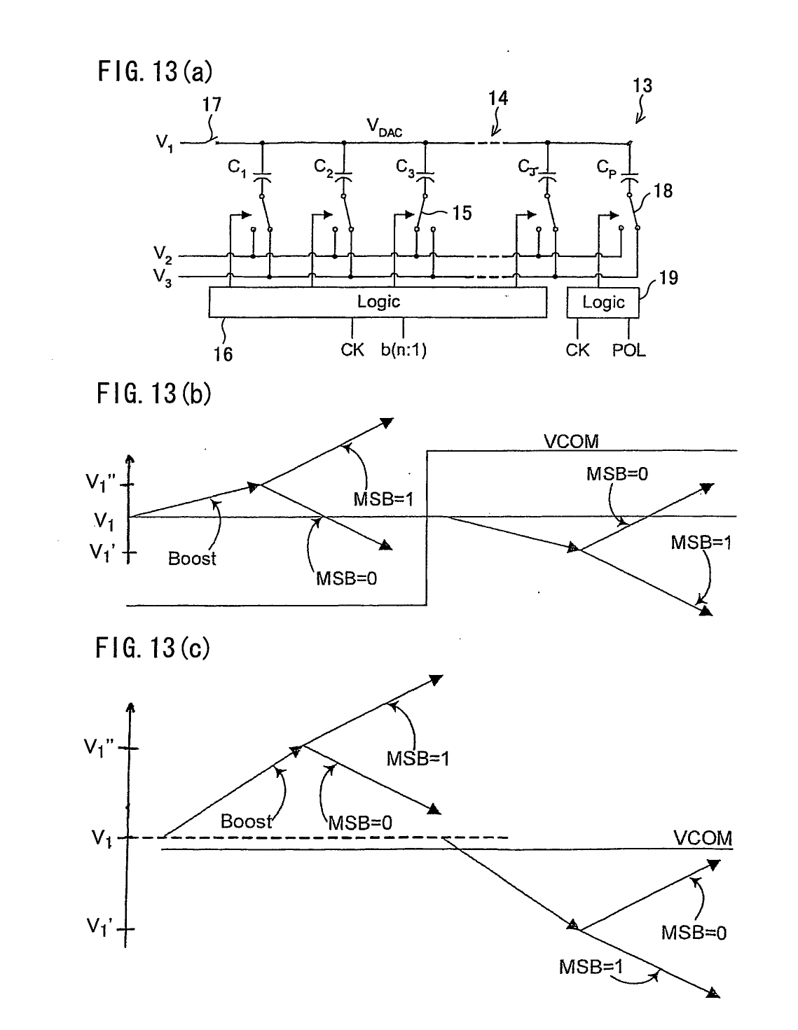

FIG. 13(a) shows a converter according to a third embodiment of the present invention. This embodiment corresponds generally to the converter of FIG. 12(a), and only the differences will be described here.

In the embodiment of FIG. 13(a), the logic circuit 19 that controls the connection of the second terminal of the boost capacitor C_{P} receives as input a timing signal CK and a state signal indicative of the state of a system that is being controlled by the converter 13. FIG. 13(a) shows the state signal as a signal POL that indicates the polarity of a liquid crystal display that is being driven by the converter, but the invention is not limited to this particular state signal. In general, the state signal input to the logic circuit 19 may be any signal that varies in time and that represents a state of the system that is being driven by the converter.

In this embodiment, the logic circuit 19 is arranged such that the direction of injection of charge across the boost capacitor C_{P} is dependent on the value of the state signal that is input into the logic circuit 19. For example, where the input state signal represents the polarity of a liquid crystal display that is being driven by the converter, the logic circuit 19 may control the switch 18 so that charge is injected across the boost capacitor C_{P} in one direction if the value of the polarity signal indicates that the polarity of the liquid crystal display is positive, and may control the switch 18 so that charge is injected across the boost capacitor C_{P} in the opposite direction if the value of the polarity signal indicates that the polarity of the liquid crystal display is negative. (As explained above, the “polarity” of the liquid crystal display indicates whether the liquid crystal should be driven with a positive voltage or with a negative voltage in the current row time).

In the converter of FIG. 13(a), the effect of the boost capacitor C_{P} is to offset the voltage about which the output voltage range is based (or the voltage about which the output voltage range is centred in the case of a bi-directional DAC) above the reference voltage V₁ to which the converter zeros for one value of the polarity signal input to the logic circuit 19, and to offset the voltage about which the output voltage range is based below the reference voltage V₁ to which the converter zeros for another value of the polarity signal input into the logic circuit 19. This is shown in FIG. 13(b). In one cycle, the effect of the boost capacitor is to boost the voltage from V₁ to V₁″, whereas in another cycle the effect of the boost capacitor is to decrease the voltage from V₁ to V₁′. The voltages may obey the following relationship: (V₁″−V₁)=(V₁−V₁′).

A converter of this embodiment may be used to supply the pixel voltages V_{PIXEL} in a drive scheme in which a display is driven using an alternating counter electrode voltage, as in the drive scheme of FIG. 2(b). When the voltage about which the output voltage range is based is boosted to V₁″ the DAC output voltages may be used to supply the pixel voltages in a period where the counter electrode voltage VCOM is low and provide a positive voltage across the liquid crystal, and when the voltage about which the output voltage range is based is boosted to V₁′ the DAC output voltages may be used to supply the pixel voltages in a period where the counter electrode voltage VCOM is high and provide a negative voltage across the liquid crystal. An alternating counter electrode voltage VCOM is superimposed in FIG. 2(b). With a converter of this embodiment, it is possible to reduce the difference between the high and low values of VCOM, so that it may be driven more easily.

This embodiment may also be used to supply the pixel voltages in a drive scheme in which a constant counter electrode voltage VCOM is used, and FIG. 13(c) shows the output voltages of the converter 13 of FIG. 13(a) with a superimposed constant counter electrode voltage. When the voltage about which the output voltage range is based is boosted to V₁″ the DAC output voltages may be used to supply pixel voltages to provide a positive voltage across the liquid crystal, and when the voltage about which the output voltage range is based is boosted to V₁′ the DAC output voltages may be used to supply pixel voltages to provide a negative voltage across the liquid crystal. In the embodiment of FIG. 13(c) it is however necessary for the difference between V₁″ and V₁ to be greater than the difference between V₁″ and V₁ in FIG. 13(b), and this requires that a larger boost capacitor must be used.

In the above description of the embodiment of FIG. 13(a) it has been assumed that charge is injected across the boost capacitor C_{P} in every decoding phase, and that the direction of charge injected into the boost capacitor C_{P} changes in accordance with the polarity signal, or other state signal, input into the logic circuit 19. (The logic circuit connects the lower plate to V₂ in the zeroing phase and to V₃ in the decoding phase for one value of the polarity signal, and vice versa for the other value of the polarity signal.) In a modified embodiment it would be possible for charge to be injected into the boost capacitor C_{P} for one value of the polarity signal (or other state signal) and for no charge to be injected for the other state of the polarity signal (or other state signal). In this embodiment, the voltage about which the output voltage range is based would remain as V₁ for one value of the polarity signal, and would be increased to V₁″ (or decreased to V₁′) for the other value of the liquid crystal polarity or other state signal. When the voltage about which the output voltage range is based is boosted to V₁″ the DAC output voltages may be used to supply the pixel voltages in a period where the counter electrode voltage VCOM is low and provide a positive voltage across the liquid crystal, and when the voltage about which the output voltage range is based is boosted to V₁′ the DAC output voltages may be used to supply the pixel voltages in a period where the counter electrode voltage VCOM is high and provide a negative voltage across the liquid crystal.

The above description refers to a state signal that has two possible values. The invention is not however limited to this, and it is possible for the state signal to have more than two values. For example, some liquid crystal display devices have two gate driver circuits, and the gate lines are arranged such that the gate lines on one side of the display are driven by one gate driver circuit and the gate lines on the other side of the display are driven by the other gate driver circuit. In this case, the charge injected by the pixel switches could be different on one side of the display compared to the other side, so the offset required to remove flicker may be different on one side of the display compared to the other side. If a single DAC were to drive pixels on both sides of the display, a state signal having four possible states (left side or right side; polarity high or low) would be required. (Use of a state signal having two or possible states may require more than the one boost capacitor shown in FIG. 13(a) to be provided—a single bi-capacitor can provide at most three states if it is a bidirectional capacitor, namely: boost up, boost down and no boost.)

In principle, the same approach could be used to provide a different offset to each row, or even to each pixel individually, to remove flicker on a row-by-row or pixel-by=pixel basis.

In principle, this embodiment could also be effected by providing two boost capacitors, with one boost capacitor being enabled for injection charge in one direction for one value of the polarity signal (or other state signal) and with the other boost capacitor being enabled for injection of charge in the opposite direction for the other state of the polarity signal (or other state signal). This embodiment would, however, have the disadvantage that any mismatch between the two boost capacitors could result in an unintended offset between the two voltage ranges, thereby causing flicker in a display driven by the converter.

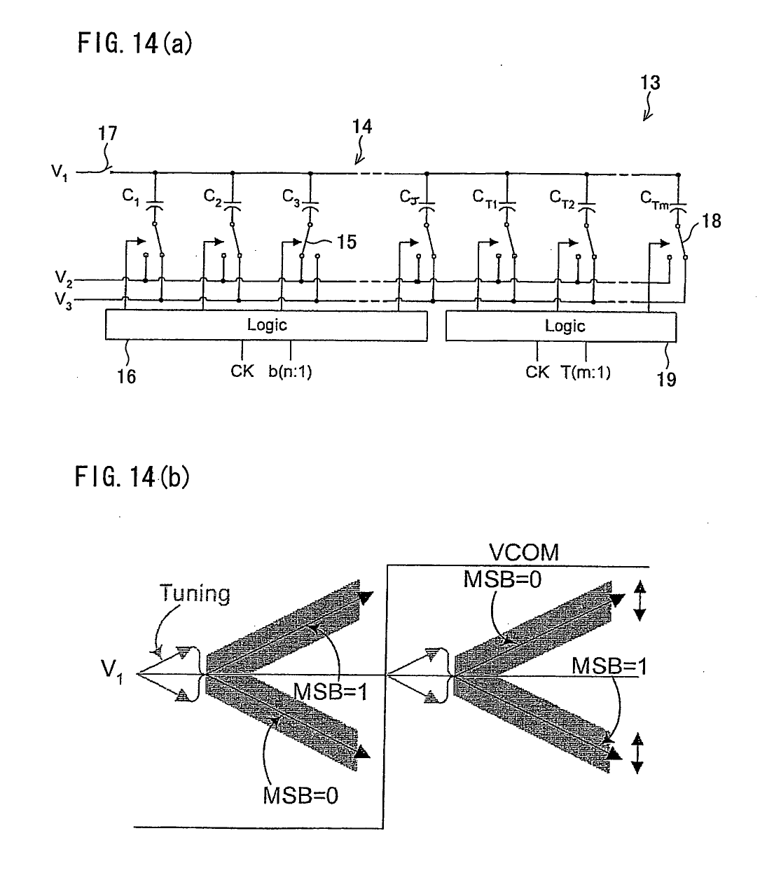

FIG. 14(a) shows a converter 13 according to a fourth embodiment of the present invention. Only the differences between this embodiment and previous embodiments will be described.

In FIG. 14(a), the converter 13 comprises a plurality of boost capacitors C_{T1} . . . C_{Tm}. Three boost capacitors are shown in FIG. 14(a), but the invention is not limited to this particular number of boost capacitors.

In this embodiment, the logic circuit 19 controls the connection of the lower plate of each boost capacitor independently from the connection of the other boost capacitor(s). That is, the state of the switch 18 controlling the connection of the second plate of the first boost capacitor C_{T1} may be controlled independently of the state of the switch controlling the connection of the second plate of every other boost capacitor C_{T2} . . . C_{Tm}.

In this embodiment, the boost capacitors are “tuning” boost capacitors, and the logic circuit 19 receives as input a timing signal CK and an m-bit word of tuning data T(m:1), where m is the total number of the tuning boost capacitors provided.

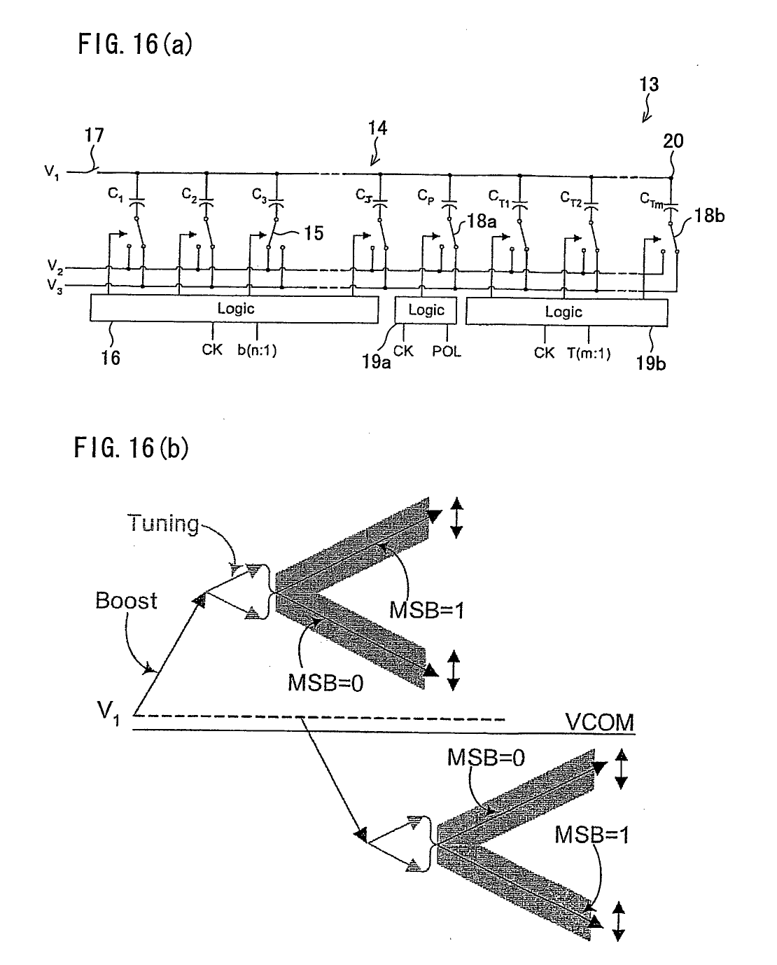

In the embodiments of FIGS. 12 and 13(a), the single boost capacitor C_{P} gives a fixed offset which cannot be adjusted after manufacture. The tuning boost capacitors C_{T1} . . . C_{Tm} of FIG. 14, in contrast, may be selectively enabled during operation, in accordance with the tuning data word. (In embodiments in which both a boost capacitor C_{P} and one or more tuning boost capacitors are provided, for example as described with reference to FIG. 16(a) below, the value of the boost capacitor would be chosen to adjust the voltage about which the DAC output range is based to approximately the required value. The voltage adjustment could then be fine-tuned in use using the tuning boost capacitor(s).)

As an example, if there are three tuning boost capacitors and the input tuning data word has the value “101”, the logic circuit may be configured such that charge is injected across the first and third tuning boost capacitors, whereas no charge is injected across the second tuning booster capacitor. Whether charge is injected across a particular tuning boost capacitor is determined, in this embodiment, by the respective bit of the input tuning data word.

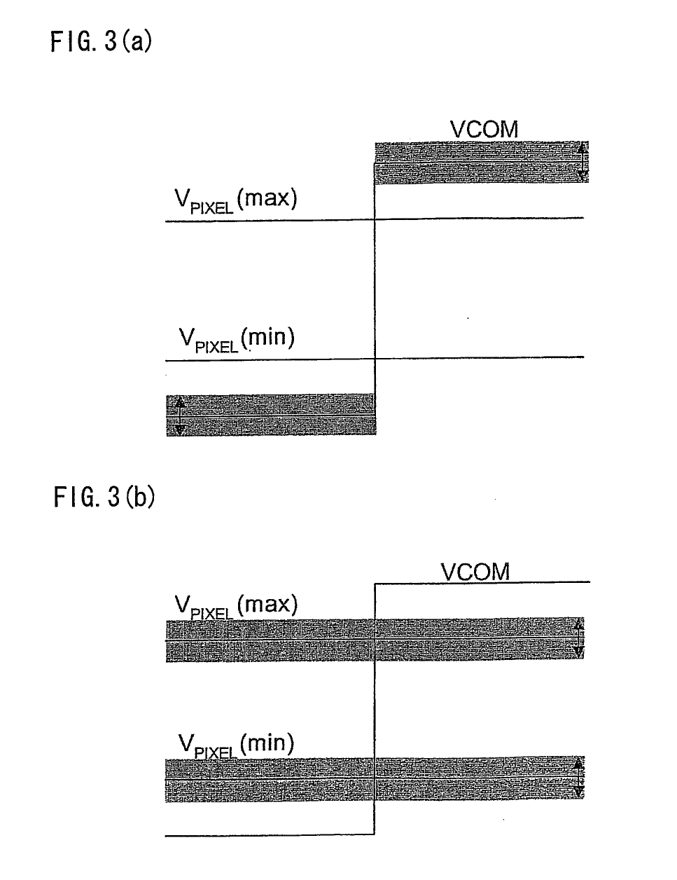

A converter of this embodiment of the present invention may be used to reduce or remove flicker in a display device. FIG. 14(b) shows the output voltage range of the converter 13 of FIG. 14(a), and it can be seen that, for any value of the input digital data b(n:1), the converter can deliver a range of output voltages (denoted by the shaded region in FIG. 14(b)), centred around the output voltage given by equation (4) for that input digital data code. A converter of this embodiment may therefore be used to provide the pixel voltages in a drive scheme similar to that shown in FIG. 3(b), in which an offset is applied to the pixel voltages to ensure that the absolute value of the voltage applied across the liquid crystal material is the same in both positive and negative cycles.

Once tuning data that eliminate flicker have been determined, they may be stored elsewhere in the system.

In the embodiment of FIG. 14(a), the tuning boost capacitors preferably operate bi-directionally, so that they can boost the output voltage of the converter 13 either above or below the normal output voltage (that is above or below the output voltage in the absence of the tuning boost capacitors). This requires that the logic circuit 19 control the connection of the lower plates of the tuning boost capacitors in the general manner described above with reference to the bi-directional DAC of FIG. 6. This has the advantage of giving a wide range of tuning, while minimising the size of the additional capacitors required (and therefore minimising the power required). In principle, however, the DAC may be arranged such that such charge can be injected in only one direction across the tuning boost capacitors.

The tuning boost capacitors may be scaled in a binary manner, such that C_{Ti}=2⁽ⁱ⁻¹⁾C_{T1}. Alternatively, the tuning boost capacitors may be scaled according to a thermometer coding in which there is one capacitor for each possible input code, so that an input tuning data word of 001 would cause charge to be injected across one tuning boost capacitor, an input tuning data word of 010 would cause charge to be injected across two tuning boost capacitors, and so on. The invention is not, however, limited to these possibilities, and the tuning boost capacitors may be scaled in any suitable manner.

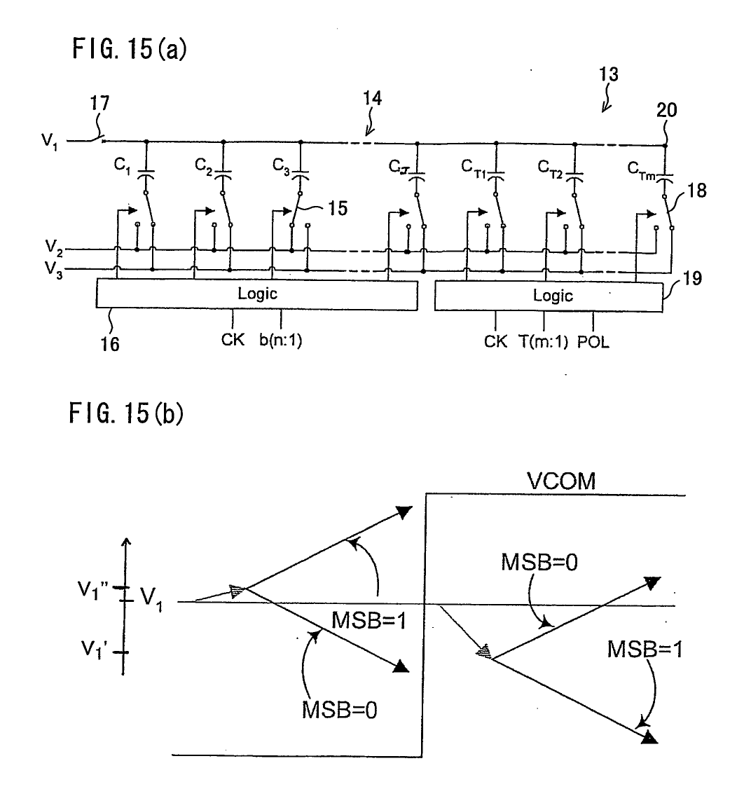

FIG. 15(a) shows a converter according to a further embodiment of the present invention. This embodiment is generally similar to the embodiment of FIG. 14(a), and only the differences will be described here.

In the embodiment of FIG. 15(a), the logic circuit 19 receives three inputs—a timing signal CK, a tuning data word T(m:1), and a polarity signal POL (or other state signal). The logic circuit 19 may be configured that the charge injected across the tuning boost capacitors for a given value of the input tuning data word T(m:1) is dependent on the value of the polarity signal (or other state signal). This allows independent adjustment of the output of the converter 13 for each value of the polarity signal (or other state signal). This is illustrated in FIG. 15(b), which shows the range of output voltages provided by the converter 13 of FIG. 15(a). It can be seen that, whereas previous embodiments provide for the voltage about which the output voltage range is based to be boosted by equal amounts above or below the reference voltage V₁, in FIG. 15(a) this is not the case. The amount by which the voltage about which the output voltage range is based is boosted above the voltage V₁ in one period is not equal to the amount by which the voltage about which the output voltage range is based is boosted below the voltage V₁ in another period. (In FIG. 15(b), (V₁″−V₁)<(V₁−V₁′) but this embodiment may alternatively be arranged such that (V₁″−V₁)>V₁−V₁′).)

FIG. 16(a) shows a converter 13 according to a further embodiment of the present invention. This embodiment is generally similar to previous embodiments, and only the differences will be described here.

In this embodiment, the converter 13 comprises two groups of boost capacitors. A first group of boost capacitors, which in this embodiment includes a single boost capacitor C_{P}, is controlled by a first logic circuit 19a. The connection of the lower plate of each capacitor of the first group of boost capacitors is controlled by a respective switch 18a, which is controlled by a respective output from a first logic circuit 19a. Although the first group of boost capacitors is shown as containing only a single capacitor in FIG. 16(a), the first group may in principle contain two or more boost capacitors.

The converter 13 further comprises a second group of boost capacitors, in this example a group of tuning boost capacitors C_{T1} . . . C_{Tn}. The connection of the lower plate of each capacitor of the tuning boost capacitors is controlled by a respective switch 18b, which is controlled by a respective output from the second logic circuit 19b.

In FIG. 16(a) the reference voltages to which the lower plate of each capacitor of the first group of boost capacitors C_{P} may be connected are the same reference voltages V₂, V₃ to which the lower plates of the DAC capacitors C₁ . . . C_{J} may be connected, and the reference voltages to which the lower plate of each capacitor of the second group of boost capacitors C_{T1} . . . C_{Tm} may be connected are also the same reference voltages V₂, V₃ to which the lower plates of the DAC capacitors C₁ . . . C_{J} may be connected, but the invention is not limited to this. The reference voltages to which the lower plate of each capacitor C_{P} of the first group of boost capacitors may be connected could be different from the reference voltages V₂, V₃. The reference voltages to which the lower plate of each capacitor C_{T1} . . . C_{Tm} of the second group of boost capacitors may be connected could be different from the reference voltages V₂, V₃ and/or could be different from the reference voltages to which the lower plate of each capacitor C_{P} of the first group of boost capacitors may be connected.

The input to the first logic circuit 19a is independent of the input to the second logic circuit 19b. Moreover, the input to each logic circuit 19a,19b is independent of the input data code input to the DAC. In the embodiment of FIG. 16(a), the first logic circuit 19a receives as input a timing signal CK and a polarity signal POL (or other state signal) indicative of the state of a system being driven by the converter, and the second logic circuit 19b receives as input a timing signal CK and a tuning data word T(m:1). FIG. 16(a) shows three tuning boost capacitors provided, in which case the tuning data word T(m:1) will be a three-bit tuning data word, but the invention is not limited to the use of three tuning boost capacitors, and more than three tuning boost capacitors or fewer than three tuning boost capacitors may be provided.

As in the embodiment of FIG. 14(a), each output of the second logic circuit 19b is independent of the other outputs of the second logic circuit 19b. In operation, charge may be injected across the boost capacitor C_{P} and/or across one of more of the tuning boost capacitors, in the manner described hereinabove. The boost capacitor C_{P} and/or the tuning boost capacitors C_{T1} . . . C_{Tn} may be bi-directional capacitors so that charge may be injected in either direction, or they may be uni-directional capacitors such that charge is injected only in one direction across the capacitors.

In the embodiment of FIG. 16(a), the direction of charge injection across the boost capacitor C_{P} is determined by the value of the polarity signal POL (or other state signal) input to the first logic circuit 19a. The injection of charge across the tuning boost capacitors C_{T1} . . . C_{Tn} is controlled as described with reference to FIG. 14(a) above.

FIG. 16(b) shows typical output voltages for the converter 13 of FIG. 16(a). The effect of the boost capacitor C_{P} is to boost the voltage about which the output voltage range is based above or below the reference voltage V₁ (to which the upper plates of the capacitors are connected in the zeroing phase). This is indicated by the arrows labelled “boost” in FIG. 16(b). The DC level about which the output voltage range is based may then be further adjusted by the tuning boost capacitors, as indicated by the arrows labelled “tuning” in FIG. 16(b).

In this embodiment, the same capacitors are used for both positive and negative polarity—the same tuning capacitors are used, regardless of the value of the POL signal, whereas in the embodiment of FIG. 15(a) a particular tuning data code may select different groups of tuning capacitors dependent on the value of the POL signal. Thus, matching of voltages is improved compared with the embodiment of FIG. 15(a), and the chance of flicker occurring in a display driven by the converter is reduced.

A converter of the embodiment of FIG. 16(a) may be used to supply the pixel voltages V_{PIXEL} in a drive scheme in which the counter electrode voltage VCOM has a constant value, as in FIG. 2(a). A constant counter electrode voltage VCOM has been superimposed on the output voltages shown in FIG. 16(b). When the voltage about which the output voltage range is based is boosted above V₁ the DAC output voltages may be used as pixel voltages to provide a positive voltage across the liquid crystal, and when the voltage about which the output voltage range is based is boosted below V₁ the DAC output voltages may be used as pixel voltages in a period to and provide a negative voltage across the liquid crystal. The output voltages may be “tuned” using the tuning data word to ensure that the magnitude of the voltage applied across the liquid crystal material when a positive voltage is applied is equal to the magnitude of the voltage applied across the liquid crystal material when a negative voltage is applied, to eliminate flicker.

In this embodiment, by use of a suitable boost capacitor C_{P}, it may be possible to connect the counter electrode to ground, thereby overcoming the problem of electro-static discharge.

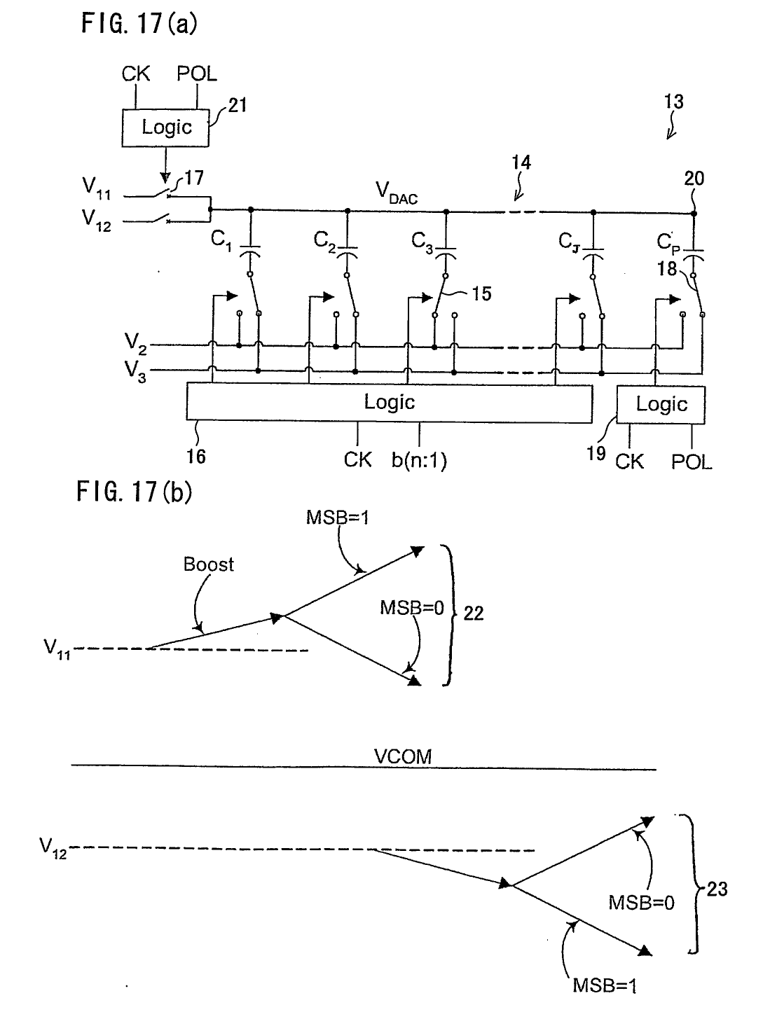

FIG. 17(a) shows a converter 13 according to a further embodiment of the present invention. This embodiment corresponds generally to the embodiment of FIG. 13(a), and only differences will be described here. In the embodiment of FIG. 17(a), the upper plates of the switching DAC capacitors C₁ . . . C_{J} and the boost capacitor C_{P} may be connected to either a reference voltage V₁₁ or to a reference voltage V₁₂, where V₁₁ ¹ V₁₂. This may be accomplished using a suitable switching arrangement, such as a switch 17 controlled by a logic circuit 21. In the zeroing phase, the output voltage to which the converter zeroes is either V₁₁ or V₁₂.

In the embodiment of FIG. 17(a), whether the upper plates of the capacitors are connected to the reference voltage V₁₁ or to the reference voltage V₁₂ is independent of the input digital data code. In the embodiment of FIG. 17(a), the input to the logic circuit 21 is a timing signal CK and a state signal relating to the system being driven by the converter 13. The input digital data code b(n:1) is not input to the logic circuit 21, and does not influence the switch 17.

The state signal that is input to the logic circuit 21 may be the same state signal that is input to the logic circuit 19 controlling the connection of the lower plate of the boost capacitor C_{P}. This is illustrated in FIG. 17(a), in which a polarity signal POL is input to both the logic circuit 21 and to the logic circuit 19. Alternatively, the state signal that is input to the logic circuit 21 may be different from the state signal that is input to the logic circuit 19 controlling the connection of the lower plate of the boost capacitor C_{P}. For example, in the case of a converter driving a liquid crystal display in which gate lines on the left side of the display are driven by one gate driving circuit and gate lines on the right side of the display are driven by another gate driving circuit, the left-right signal may be input to one of the logic circuits and the polarity signal may be input to the other of the logic circuits.

In the decoding phase, the switching arrangement is controlled to isolate the upper plates of the switching DAC capacitors C₁ . . . C_{J} and the upper plate of the boost capacitor C_{P} from both the reference voltages V₁₁, V₁₂.

In the absence of the boost capacitor C_{P}, the output voltages from the converter 13 in a decoding phase would consist of either a range of output voltages above and below the reference voltage V₁₁ or a range of output voltages above and below the reference voltage V₁₂, depending on whether V₁₁ or V₁₂ had been selected in the zeroing phase. These output voltage ranges would be given by equation (4), but with V₁ replaced by V₁₁ or V₁₂ (and with C_{TERM} set to zero if no terminating capacitor is provided). By providing the boost capacitor C_{P}, and by controlling both the selection of the reference voltage V₁₁ or the reference voltage V₁₂ and the connection of the second terminal of the boost capacitor C_{P} on the basis of the polarisation signal POL (or other state signal), it is possible to boost the voltage about which the output voltage range is based above the voltage V₁₁ or below the output voltage V₁₂ as shown in FIG. 17(b) (or, conversely, to boost the voltage below the reference voltage V₁₁ and above the reference voltage V₁₂).

It will be seen that the output voltage ranges shown in FIG. 17(b) haves a similar form to the output voltage ranges shown in FIG. 13(b) or 13(c). However, in FIG. 17(b), part of the voltage offset between the two output ranges arises from the difference between reference voltage V₁₁ and the reference voltage V₁₂, and only part of the difference arises from the effect of the boost capacitor C_{P}. This allows the boost capacitor C_{P} to be smaller in the embodiment of FIG. 17(a) than in the embodiment of FIG. 13(a).

In general, the values of the reference voltages V₁₁, V₁₂ will be fixed by the supply rails available in the system. In a typical system it is unlikely that the supply rails will be appropriately spaced to provide two output voltage ranges that allow use of a driving scheme using a constant counter electrode voltage VCOM—in general, the supply rails will supply a positive voltage V_{dd} fad and ground potential. However, the provision of the boost capacitor C_{P} in the embodiment of FIG. 17(a) enables the offset between the two output ranges 22, 23 to be adjusted to the desired value for a given driving scheme—the offset between the two output ranges 22, 23 is not fixed by the supply rails available in the system.

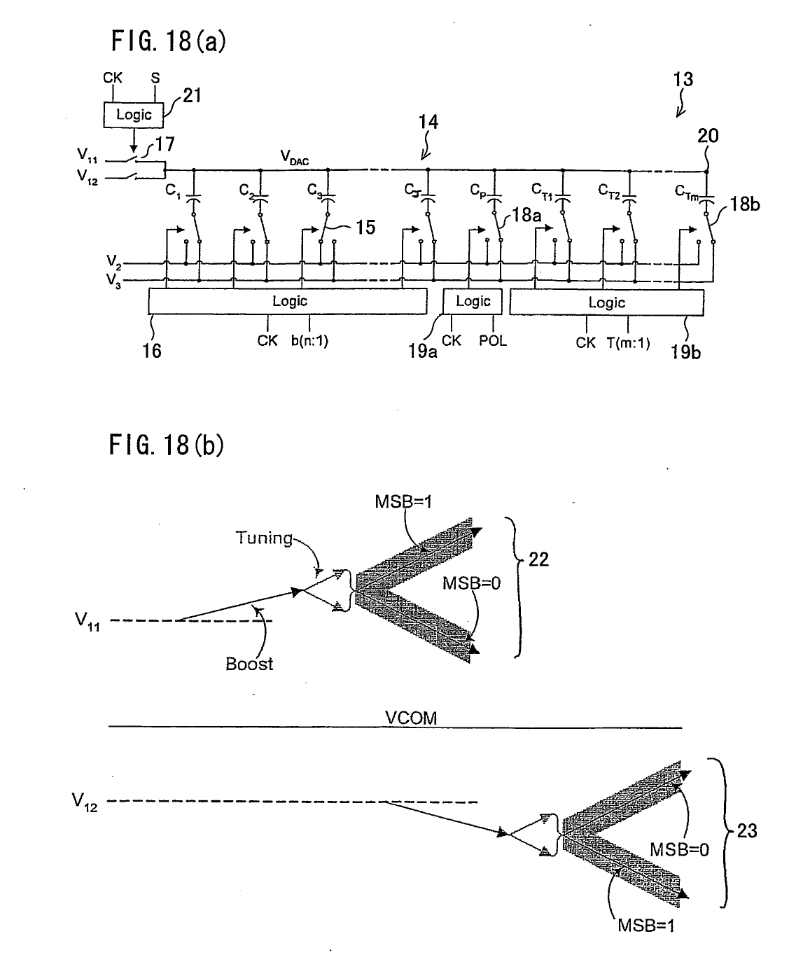

The use of two reference voltages V₁₁, V₁₂ and a suitable switching arrangement to connect the upper plates of the capacitors of the converter to one or other of these voltages in the zeroing phase may be applied to every embodiment of the present invention. By way of example, FIG. 18(a) illustrates a further converter 13 of the present invention, which corresponds generally to the converter 13 of FIG. 16(a), but which is provided with a switching arrangement 17 and a logic circuit 21 for connecting the upper plates of the capacitors of the switching capacitor DAC 14, of the boost capacitor C_{P}, and of the tuning capacitors C_{T1} . . . C_{Tm} to either a voltage reference V₁₁ or a voltage reference V₁₂ (V₁₁ ¹ V12) in the zeroing phase.

FIG. 18(b) shows the voltage output ranges 22, 23 of the converter 13 of FIG. 18(a). This embodiment retains all advantages of the embodiment of FIG. 17(a) and, moreover, flicker may be eliminated from a display that is driven by the converter using the tuning boost capacitors C_{T1} . . . C_{Tm}. The output voltage ranges 22,23 of the converter 13 are suitable for use as pixel voltages in a driving scheme having a constant counter electrode voltage VCOM, and a constant counter electrode voltage is superimposed in FIG. 18(b). The converter 13 of FIG. 18(a) may, as with the converter of FIG. 16(a), be used in a driving scheme in which the counter electrode voltage VCOM is connected to ground, thereby overcoming the problem of electro-static discharge. Moreover, compared to the embodiment of FIG. 16(a), the embodiment of FIG. 18(a) may use a smaller boost capacitor C_{P} as described with reference to the embodiment of FIG. 17(a) above.

The use of two reference voltages V₁₁, V₁₂ and a suitable switching arrangement to connect the upper plates of the capacitors of a switched capacitor DAC to one or other of these voltages in the zeroing phase may in principle be applied to any converter having a switched capacitor DAC.

In the embodiments described above, the capacitors C₁ . . . Cⱼ of the switched capacitor DAC 14 may be arranged such that Cᵢ=2⁽ⁱ⁻¹⁾C₁, but the invention is not limited to this.

The invention has been described with reference to a buffer-less DAC. In principle, however, the invention may be applied to a buffered DAC, in which a unity gain output buffer is provided in FIG. 4.

The invention has been described above with reference to a DAC that is being used to drive a crystal display device. The invention may, however, be used wherever it would be desirable for a single DAC to generate voltages across two or more different output ranges depending upon the state of the system that is being driven by the DAC.

In the embodiments of FIGS. 17(a) and 17(b), the upper plates of the DAC capacitors C₁ . . . C_{J}, the boost capacitor C_{P} and, in FIG. 18(a), the tuning boost capacitors C_{T1} . . . C_{Tm} may be connected to one of two reference voltages V₁₁, V₁₂ in the zeroing phase. The invention is not limited to this, however, and a converter may comprise three or more different reference voltage sources and a switching arrangement for connecting the upper plates of the capacitors to any one of the three or more reference voltages during the zeroing phase.

In the embodiments described above, the lower plates of the boost capacitors and tuning boost capacitors are connected, via the respective switches, to one of reference voltage V₂ and V₃, which are the same reference voltages to which the lower plates of the capacitors Cᵢ of the switched capacitor DAC are connected. This reduces the number of supply voltages required.

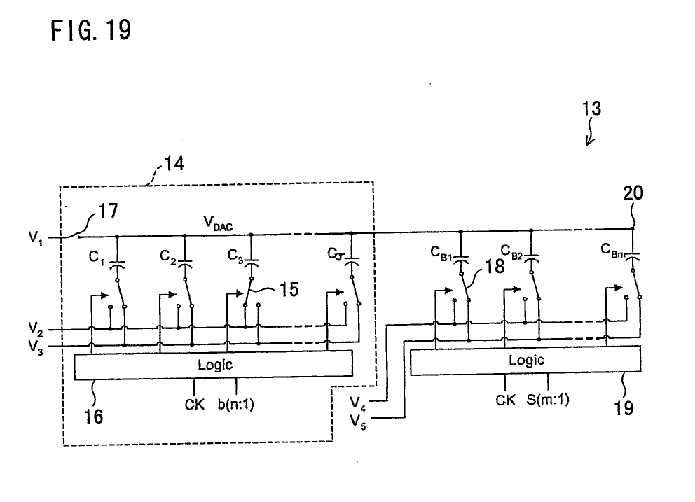

In principle however, the lower plates of the boost capacitors and/or tuning boost capacitors may be connected, via the respective switches, to reference voltages which are not the same as the reference voltages to which the lower plates of the capacitors Cᵢ of the switched capacitor DAC are connected. This is illustrated in FIG. 19, which is a block circuit diagram of a converter according to a further embodiment of the invention.

The converter 13′ of FIG. 19 corresponds generally to the converter of FIG. 11, except that the lower plates of the boost capacitors C_{B1} . . . C_{Bm} are not switched between the same reference voltages as the lower plates of the DAC capacitors C₁ . . . Cⱼ. In the converter 13′ of FIG. 19 the lower plates of the boost capacitors C_{B1} . . . C_{Bm} are switched between a reference voltage V₄ and a reference voltage V₅ (V₄ ¹ V₅), whereas the lower plates of the DAC capacitors C₁ . . . C_{J} are switched between a reference voltage V₂ and a reference voltage V₃ (V₂ ¹ V₃) . The reference voltages V₂, V₃, V₄, V₅ may all be different from one another (or, in principle, three of the reference voltages may be different so that, for example V₂=V₄ ¹ V₃ ¹ V₅).

Other features of the converter 13′ of FIG. 19 correspond to the respective features of the converter 13 of FIG. 11, and their description will not be repeated.

Moreover, where one or more tuning boost capacitors and one or more boost capacitors are provided, as in the embodiment of FIG. 16(a), it would in principle be possible for the lower plates of the boost capacitor(s) to be connected, via the respective switches, to reference voltages which are different from the reference voltages to which the lower plates of the tuning boost capacitors are connected and which are also different from the reference voltages to which the lower plates of the capacitors Cᵢ of the switched capacitor DAC are connected.

For a fuller understanding of the nature and advantages of the invention, reference should be made to the ensuing detailed description taken in conjunction with the accompanying drawings.

The invention being thus described, it will be obvious that the same way may be varied in many ways. Such variations are not to be regarded as a departure from the spirit and scope of the invention, and all such modifications as would be obvious to one skilled in the art are intended to be included within the scope of the following claims.

### INDUSTRIAL APPLICABILITY

A converter of the present invention may be used, for example, for driving matrix columns of a liquid crystal display. A particular application of such a converter is in small display panels for portable applications where it is particularly desirable to minimise power consumption.

1. A digital/analogue converter for converting an input n-bit digital code, where n is an integer greater than one, comprising: a switched capacitor digital/analogue converter having a plurality of capacitors, a first terminal of each capacitor being connected to an output of the converter, and a second terminal of each capacitor being connectable, dependent on a respective bit of the input digital code, to either a first reference voltage or a second reference voltage different from the first reference voltage;
and further comprising a first further capacitor, a first terminal of the first further capacitor being connected to the output of the converter; and a first switching arrangement for connecting a second terminal of the further capacitor to either a third reference voltage or a fourth reference voltage different from the third reference voltage, wherein an input to the first switching arrangement is independent of the input digital code.

2. A converter as claimed in claim 1 wherein the connection of the second terminal of the first further capacitor is maintained throughout a decoding phase.

3. A converter as claimed in claim 1 wherein the switched capacitor digital/analogue converter comprises n capacitors.

4. A converter as claimed in claim 1 wherein the converter comprises two or more first further capacitors, and wherein the first switching arrangement is such that the choice of reference voltage to be connected to the second terminal of one of the first further capacitors is independent of the choice of reference voltage to be connected to the second terminal of the or each other first further capacitor.

5. A converter as claimed in claim 1, wherein the switched capacitor digital/analogue converter is a bi-directional switched capacitor digital/analogue converter.

6. A converter as claimed in claim 1, wherein the input to the first switching arrangement comprises a clock signal.

7. A converter as claimed in claim 1, wherein the input to the first switching arrangement comprises tuning data.

8. A converter as claimed in claim 1, wherein the input to the first switching arrangement comprises a signal indicative of the state of a system.

9. A converter as claimed in claim 1 and further comprising at least one second further capacitor, a first terminal of the or each second further capacitor being connected to the output of the converter; and a second switching arrangement for connecting a second terminal of the or each second further capacitor to either a fifth reference voltage or to a sixth reference voltage different from the fifth reference voltage, wherein an input to the second switching arrangement is independent of the input n-bit digital code and is independent of the input to the first switching arrangement.

10. A converter as claimed in claim 9 wherein the input to the first switching arrangement comprises a clock signal and tuning data, and the input to the second switching arrangement comprises a clock signal and a signal indicative of the state of a system.

11. A converter as claimed in claim 1 and further comprising a third switching arrangement for connecting, during a zeroing phase, the first terminals of the capacitors of the switched capacitor digital/analogue converter to a reference voltage.

12. A converter as claimed in claim 11 wherein the third switching arrangement is adapted to, in a decoding phase, isolate the first terminal of each capacitor of the switched capacitor digital/analogue converter from the reference voltage.

13. A converter as claimed in claim 11 wherein the third switching arrangement connects, during the zeroing phase, the first terminals of the capacitors of the switched capacitor digital/analogue converter to one of the first and second reference voltages.

14. A converter as claimed in claim 11 wherein the third switching arrangement connects, during the zeroing phase, the first terminals of the capacitors of the switched capacitor digital/analogue converter to a reference voltage different from both the first reference voltage and the second reference voltage.

15. A converter as claimed in claim 11 wherein the third switching arrangement connects, during a zeroing phase, the first terminals of the capacitors of the switched capacitor digital/analogue converter to either a seventh reference voltage or to an eighth reference voltage different from the seventh reference voltage, and wherein an input to the third switching arrangement is independent of the input digital code.

16. A converter as claimed in claim 1 wherein the converter is a bufferless converter and the output is for direct connection to a capacitive load.

17. A converter as claimed in claim 1 wherein the third reference voltage is equal to the first reference voltage, and the fourth reference voltage is equal to the second reference voltage.

18. A converter as claimed in claim 9, wherein the fifth reference voltage is equal to the first reference voltage, and the sixth reference voltage is equal to the second reference voltage.

19. A display driver comprising a converter as defined in claim 1.

20. A display comprising an image display layer and a driver as defined in claim 19 for driving at least a selected region of the image display layer.

21. A display as claimed in claim 20 wherein the input to the first switching arrangement is dependent on a state of the image display layer.

22. A display as claimed in claim wherein the image display layer is a layer of liquid crystal material.

23. A display as claimed in claim 21 wherein the image display later is a layer of liquid crystal material, the input to the first switching arrangement is dependent on the polarity of the liquid crystal material.
